(19) United States
(12) Patent Application Publication
(10) Pub. No.: US 2009/0096103 A1
(43) Pub. Date: Apr. 16, 2009

(54) SEMICONDUCTOR DEVICE AND METHOD FOR FORMING BARRIER METAL LAYER THEREOF

(76) Inventor: Kyung-Min Park, Gangnam-gu (KR)

Correspondence Address: SHERR & VAUGHN, PLLC, 620 HERNDON PARKWAY, SUITE 200, HERNDON, VA, 20170, US

(21) Appl. No.: 12/202,623

(22) Filed: Sep. 2, 2008

(30) Foreign Application Priority Data
Oct. 16, 2007 (KR) 10-2007-0104013

(51) Int. Cl. H01L 21/768; H01L 23/532

(52) U.S. Cl. 257/751; 438/643; 257/E21.584; 257/E23.161

(57) ABSTRACT

A method for forming a barrier metal layer includes forming a metal compound film composed of a first metal and a second metal on sidewalls of a contact hole, and then selectively etching the metal compound film and then simultaneously forming a barrier metal layer and a first metal seed layer on sidewalls of the contact hole by performing a thermal treatment process on the metal compound film. Accordingly, the process time can be shortened because the sputtering process can be reduced by forming a barrier metal layer and a copper seed layer by reaction between the second metal material and an underlying insulating film by performing the thermal treatment process.

The present application claims priority under 35 U.S.C. §119 to Korean Patent Application No. 10-2007-0104013 (filed on Oct. 16, 2007), which is hereby incorporated by reference in its entirety.

### BACKGROUND

A metal line may be used in order to permit electrical connection between devices or between interconnections in the fabrication of a semiconductor device. A metal line may be composed of a material such as aluminum (Al) or tungsten (W), but their continued use in ultra high-integrated semiconductor device has become difficult due to a low melting point and a high specific resistance. With the need to obtain ultra high integration of semiconductor devices, the necessity of materials having low specific resistance and superior reliability of their electro-migration and stress migration characteristics increases. Copper is used as the most suitable material which can cope with these conditions. However, there is a problem that a wire for copper is difficult to etch and its corrosion is diffused, and therefore there is a considerable difficulty in its suitability.

To solve this problem and realize suitability, a single damascene process or especially, a dual damascene process may be employed. According to the damascene process, a trench is formed in an insulting layer by photo and etching processes. The trench may then be filled with a conductive material such as tungsten (W), aluminum (Al) or copper (Cu). A portion of the conductive material except for that portion which is necessary for the interconnection is then removed by etch back or CMP (Chemical Mechanical Polishing) so that the interconnection having a shape of the trench is formed. In the dual damascene process, a via hole for connecting an upper layer metal line and a lower layer metal line can be formed in a multilayer metal line, and a stepped portion generated by the metal lines can be removed, thereby making the subsequent process easier.

Recently, a copper interconnection process using electroplating (EP) is reaching the commercialization stage. In the copper interconnect process, unlike an aluminum interconnect process for forming an interconnection by a reactive ion etching method, a pattern is formed by a dual damascene process, a barrier metal is deposited, and then an interconnection is formed by the electroplating of copper. Copper electroplating, however, cannot be directly done on a barrier metal. Thus, electroplating should be carried out after thinly depositing copper as a seed layer. A representative method of the electroplating process is to sequentially deposit TaN_{X} and a Cu seed layer by a sputtering process, which is a physical vapor deposition (PVD) and then electroplating the copper.

A method for forming a copper interconnection of a semiconductor device will be described with reference to the accompanying example drawings figures.

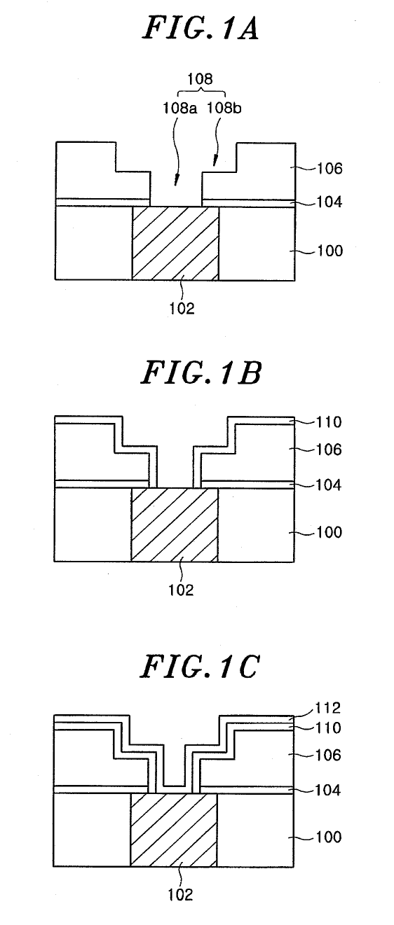

As illustrated in example FIG. 1A, etch stop layer 104 and second interlayer insulating film 106 are sequentially deposited on and/or over first interlayer insulating film 100 having lower copper line 102 formed therein. First and second interlayer insulating films 100 and 106 may be formed of a material having a low dielectric constant k, typically, a silicon oxide film. Etch stop layer 104 may be formed of, typically, a silicon nitride film SiN. Etch stop layer 104 and second interlayer insulating film 106 may then be selectively removed to expose lower copper line 102 by a predetermined process, thereby forming contact hole 108 having a dual damascene structure including via 108a and trench 108b.

As illustrated in example FIG. 1B, barrier metal layer 110 having a predetermined thickness may then be formed on and/or over the entire surface including contact hole 108 by a sputtering process. Barrier metal layer 110 may be formed of TiSiN. An etching process and a washing process may then be performed on barrier metal layer 110 until barrier metal layer 110 is provided on sidewalls of via 108a.

As illustrated in example FIG. 1C, copper seed layer 112 is formed by a sputtering process in contact hole 108 and on and/or over barrier metal layer 110. Upper copper line may then be formed by electroplating copper seed layer 112. However, such a method for forming a copper interconnection has the problem that the sputtering target cost is expensive and requires a lot of process time because a barrier metal layer and a copper layer are formed by a sputtering process.

### SUMMARY

Embodiments relate to a semiconductor device and a method for forming a barrier metal layer thereof that can reduce processing time of forming a barrier metal layer and a copper seed layer by performing a thermal treatment process on a copper compound containing the metal material.

Embodiments relate to a method for forming a barrier metal layer that may include at least one of the following steps: forming a contact hole having a damascene structure by selectively etching an insulating film on and/or over a semiconductor substrate; and then forming a self-forming film on and/or over the surface of the contact hole using a copper compound containing a metal material; and then forming a metal film and a copper seed layer by a reaction between the metal material and the insulating film through a thermal treatment process on the self-forming film.

Embodiments relate to a method for forming a barrier metal layer that may include at least one of the following steps: providing a first insulating film having a lower conductive layer formed therein; and then forming an second insulating film on the first insulating film; and then forming a contact hole having a damascene structure by selectively etching the second insulating film exposing the lower conductive layer; and then forming a first metal compound film on sidewalls of the contact hole, wherein the first metal compound film comprises copper and a second metal material; and then forming a barrier metal layer and a copper seed layer by performing a thermal treatment process on the first metal compound film to cause a reaction between the second metal material and the second insulating film.

Embodiments relate to a method that may include at least one of the following steps: providing a lower conductor over a semiconductor substrate; and then sequentially forming a nitride film as an etch stop film and an oxide film over the lower conductor; and then forming a contact hole by selectively etching the nitride film and the oxide film to expose the lower conductor; and then forming a metal compound film on sidewalls of the contact hole and on the lower conductor, wherein the metal compound film comprises a first metal and a second metal; and then selectively etching the metal compound film to expose the lower conductor; and then simultaneously forming a barrier metal layer and a first metal seed layer on sidewalls of the contact hole by performing a thermal treatment process on the metal compound film.

In accordance with embodiments, the copper compound is a copper compound containing any one selected from a metal group consisting of Zr, Hf, Mn, Zn, and Al. The self-forming film may be formed at a thickness in a range between 100 to 200 Å. The thermal treatment process may be carried out for 10 to 30 minutes at a temperature range of between 150 to 300° C.

Embodiments relate to a semiconductor device that may include at least one of the following: a lower copper line; an insulating layer formed on the lower copper line; a contact hole having a damascene structure formed in the insulating layer exposing a portion of the lower copper line; a barrier metal layer formed on sidewalls of the contact hole. In accordance with embodiments, the barrier metal layer is formed by a reaction between a metal material and a material contained in the insulating film through a thermal treatment process.

### DRAWINGS

Example FIGS. 1A to 1C illustrate a process for fabricating a copper interconnection of a semiconductor device.

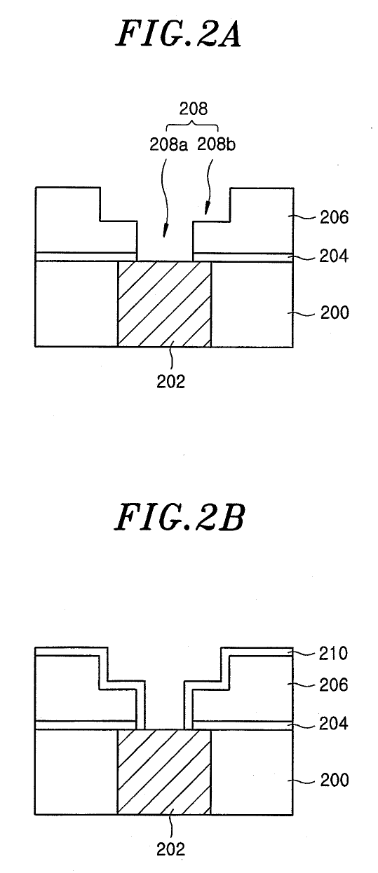

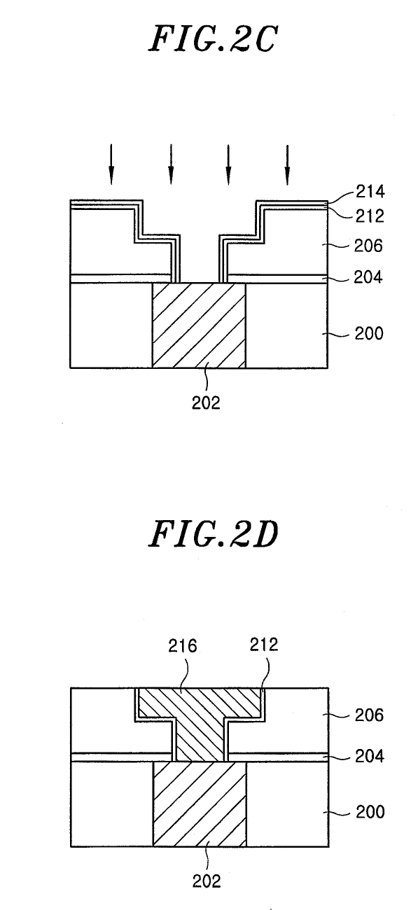

Example FIGS. 2A to 2D illustrate a process for forming a barrier metal layer of a semiconductor device in accordance with embodiments.

### DESCRIPTION

Hereinafter, a preferred embodiment of the present invention will be described in detail with reference to the accompanying drawings. In the following description, well-known functions or configurations will not be set forth in detail if it may obscure the invention in unnecessary detail.

In accordance with embodiments, a copper seed layer and a barrier metal layer are formed by a thermal treatment process after forming a self-forming film on and/or over the surface of a contact hole having a damascene structure by use of a copper compound containing a metal material.

As illustrated in example FIG. 2A, etch stop film 204 and second interlayer insulating film 206 are sequentially deposited on and/or over first interlayer insulating film 200 having lower copper line 202 formed therein. First insulating film 200 and second interlayer insulating film 206 are formed of a material having a low dielectric constant k, such as silicon oxide. Etch stopper film 204 is formed of silicon nitride SiN. Etch stop layer 204 and second interlayer insulating film 206 are selectively removed to expose lower copper line 202 by a predetermined process, thereby forming contact hole 208 having a dual damascene structure including via 208a and trench 208b.

As illustrated in example FIG. 2B, self-forming film 210 formed of a first metal compound (such as a copper compound) containing a second metal material may then be formed on and/or over the surface of contact hole 208 by a deposition process. The second metal material included in self-forming film 210 is a material readily reactive with the oxide contained in second interlayer insulating film 206 through a thermal treatment process. Such metal materials may include at least one of Zr, Hf, Mn, Mg, An, and Al. An example of the deposition process may include a sputtering process. Self-forming film 210 may be formed at a thickness in a range between 100 to 200 Å using a sputtering process. An etching and washing process may then be carried out to remove a portion of self-forming film 210 formed on and/or over the bottom surface of contact hole 208 to thereby expose the uppermost surface of lower copper line 202.

As illustrated in example FIG. 2C, metal film 212 and copper seed layer 214 may then be formed by carrying out a thermal treatment process on self-forming film 210. More specifically, by performing the thermal treatment process on self-forming film 210, the second metal material contained in self-forming film 210 is separated or otherwise diffuses from self-forming film 210 due to its chemical affinity with the oxide contained in second interlayer insulating film 206, thereby causing the second metal material to react with the oxide to form barrier metal layer 212. Because the second metal material contained in self-forming film 210 is separated therefrom, only the copper component remains in self-forming film 210, thereby forming copper seed layer 214. Such a thermal treatment process is carried out for between 10 to 30 minutes at a temperature range of between 150 to 300° C.

As illustrated in example FIG. 2D, a copper layer may then be formed by using copper seed layer 214 so as to completely bury contact hole 208. Upper copper line 216 may then be formed by removing barrier metal layer 212 and copper layer formed on and/or over second interlayer insulating film 206 by a chemical mechanical polishing (CMP) using barrier metal layer 212 formed on and/or over second interlayer insulating film 206 as an etch stopper layer.

Accordingly, embodiments may form a barrier metal layer and a copper seed layer without any sputtering process by forming a self-forming film composed of a copper compound containing a second metal material and then performing a thermal treatment process on the self-forming film. In addition, it is possible to shorten the process time because the sputtering process can be reduced by forming a barrier metal layer and a copper seed layer by performing a thermal treatment process after forming a self-forming film on and/or over the surface of a contact hole having a damascene structure by use of a copper compound containing the second metal material. Although embodiments have been described with respect to a dual damascene structure, it is equally applicable to any damascene structure requiring the formation of a barrier metal layer.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for forming a barrier metal layer comprising:
providing a first insulating film having a lower conductive layer formed therein; and then
forming an second insulating film on the first insulating film; and then
forming a contact hole having a damascene structure by selectively etching the second insulating film exposing the lower conductive layer; and then
forming a first metal compound film on sidewalls of the contact hole, wherein the first metal compound film comprises copper and a second metal material; and then
forming a barrier metal layer and a copper seed layer by performing a thermal treatment process on the first metal compound film to cause a reaction between the second metal material and the second insulating film.

2. The method of claim 1, wherein the first metal compound film is formed by a sputtering method.

3. The method of claim 2, wherein the second metal material comprises any one selected from a metal group consisting of Zr, Hf, Mn, Zn, and Al.

4. The method of claim 2, wherein the first metal compound film is formed at a thickness in a range between 100 to 200 Å.

5. The method of claim 1, wherein the second metal material comprises any one selected from a metal group consisting of Zr, Hf, Mn, Zn, and Al.

6. The method of claim 5, wherein the first metal compound film is formed at a thickness in a range between 100 to 200 Å.

7. The method of claim 1, wherein the thermal treatment process is carried out for 10 to 30 minutes at a temperature in a range between 150 to 300° C.

8. A semiconductor device comprising:
a lower copper line;
an insulating layer formed on the lower copper line;
a contact hole having a damascene structure formed in the insulating layer exposing a portion of the lower copper line;
a barrier metal layer formed on sidewalls of the contact hole, wherein the barrier metal layer is formed by a reaction between a metal material and a material contained in the insulating film through a thermal treatment process.

9. The semiconductor device of claim 8, further comprising an upper copper line formed in the insulating layer and electrically connected to the lower cooper line.

10. The semiconductor device of claim 8, wherein the metal material is one selected from a group consisting of Zr, Hf, Mn, Zn, and Al.

11. A method comprising:
providing a lower conductor over a semiconductor substrate; and then
sequentially forming a nitride film as an etch stop film and an oxide film over the lower conductor; and then
forming a contact hole by selectively etching the nitride film and the oxide film to expose the lower conductor; and then
forming a metal compound film on sidewalls of the contact hole and on the lower conductor, wherein the metal compound film comprises a first metal and a second metal; and then
selectively etching the metal compound film to expose the lower conductor; and then
simultaneously forming a barrier metal layer and a first metal seed layer on sidewalls of the contact hole by performing a thermal treatment process on the metal compound film.

12. The method of claim 11, wherein the oxide film comprises silicon oxide and the nitride film comprises silicon nitride.

13. The method of claim 11, wherein the contact hole has a dual damascene structure including a via and a trench.

14. The method of claim 11, wherein the first metal comprises copper.

15. The method of claim 14, wherein the second metal is one selected from a group consisting of Zr, Hf, Mn, Zn, and Al.

16. The method of claim 11, wherein the second metal is one selected from a group consisting of Zr, Hf, Mn, Zn, and Al.

17. The method of claim 11, wherein the second metal comprises a metal that is readily reactive with the oxide film.

18. The method of claim 11, wherein the thermal treatment process causes the second metal to diffuse from the metal compound film to react with the oxide film and thereby form barrier metal layer, the remaining first metal component forming the first metal seed layer.

19. The method of claim 11, further comprising, after simultaneously forming the barrier metal layer and the first metal seed layer:
forming an upper conductor on the barrier layer using the first metal seed layer, wherein the upper conductor is electrically connected to the lower conductor.

20. The method of claim 11, wherein the lower conductor, the first metal and the upper conductor are composed of copper.
